(19) United States
(12) Patent Application Publication
(10) Pub. No.: US 2002/0119316 A1
(43) Pub. Date: Aug. 29, 2002

(54) Protective overcoat layer for magnetic recording discs having enhanced corrosion resistance properties

(76) Inventors: Nisha Shukla, Pittsburgh, PA (US); Raj Thangaraj, Fremont, CA (US); Michael Joseph Stirniman, Fremont, CA (US); Jing Gui, Fremont, CA (US)

Correspondence Address: BUCHANAN INGERSOLL, P.C., ONE OXFORD CENTRE, 301 GRANT STREET, 20TH FLOOR, PITTSBURGH, PA, 15219, US

(21) Appl. No.: 10/015,870

(22) Filed: Dec. 12, 2001

Related U.S. Application Data
(60) Provisional application No. 60/256,858, filed on Dec. 19, 2000.

(51) Int. Cl. B05D 5/12; C23C 16/00; B05D 1/36; B32B 9/00

(52) U.S. Cl. 428/408; 427/127; 427/248.1; 427/407.1; 428/704; 428/336; 428/422

(57) ABSTRACT

A protective overcoat layer having enhanced corrosion resistance properties is provided according to the present invention for use on magnetic recording discs. The protective overcoat layer includes a doped or non-doped carbon-containing layer, and a lubricant layer on top of the carbon-containing layer, with the lubricant layer having a >CNO functional end group. The carbon-containing layer may have a thickness less than 40 Å, while the lubricant layer may have a thickness less than 20 Å.

### CROSS-REFERENCE TO RELATED APPLICATIONS

This application claims the benefit of co-pending provisional patent application Serial No. 60/256,858 entitled “Magnetic Recording Media Containing a Lubricant Layer with Enhanced Corrosion Performance”, filed on Dec. 19, 2000, the entire disclosure of which is incorporated by reference herein.

### FIELD OF THE INVENTION

The present invention is directed generally toward magnetic recording media and, more particularly, toward a protective overcoat layer for magnetic recording media having enhanced corrosion performance properties.

### BACKGROUND OF THE INVENTION

Conventional magnetic disc drives basically include magnetic recording discs having magnetic recording media thereon for magnetic storage, a read/write head for reading and writing data from and to the magnetic recording media, and electronics to control all of the basic drive functions. The majority of the current generation magnetic hard disc drives use a contact stop-start (CSS) interface method for reading and writing data from and to the magnetic recording disc. In a conventional CSS method, the read/write head begins to slide against the surface of the magnetic recording disc as the disc begins to rotate. Upon the disc reaching a predetermined rotational speed, the read/write head will float in the air above the surface of the disc and is maintained at a predetermined height (“fly height”) during reading and writing operations. Upon termination of the read/write operation, the rotation of the magnetic recording disc will slow and the read/write head will begin to slide against the surface of the disc, eventually stopping in contact with, and pressing against, the disc. Each time a read or write operation is initiated, the read/write head repeats the sequence of sliding against the surface of the disc, floating in the air, sliding against the surface of the disc, and stopping in contact with the disc. The sliding of the read/write head against the disc causes wear to the disc surface.

The magnetic recording media on the magnetic recording disc is currently protected from mechanical damage by two thin film coatings. These coatings typically include a thin layer of carbon overcoat (approximately 30-50 Å thick) and a layer of lubricant (approximately 15-25 Å thick). The carbon layer is applied to the magnetic recording media and protects the magnetic layer against damage from direct contact with the read/write head, and also serves as a corrosion barrier to prevent oxidation of the magnetic layer. The layer of lubricant is applied to the carbon layer and has viscous properties to reduce shear stresses between the read/write head and disc during contact.

In order to increase the recording areal density of magnetic recording discs, the read/write head-recording media separation, which includes fly height, poll-tip recession, overcoats on the recording media and on the read/write head, and lubricant on the recording media, must be reduced. For example, in order to improve the signal-to-noise ratio (SNR) in reading and writing from and to a disc having an areal density of approximately 100 Gbit/in², the read/write head must fly very close to the recording media surface, almost in contact therewith. The desire to reduce head-to-media separation limits the thickness of the protective thin films that may be applied for wear and corrosion resistance. If the carbon overcoat layer becomes so thin that is not continuous, environmental oxidizing species, such as water and other contaminants, will contact the recording media causing media corrosion. Media corrosion is a major cause of disc drive failure. Also, the read/write head may come into direct contact with the recording media causing wear to, and loss of, the recording media.

To improve the reliability of the thin carbon overcoat, improving the properties of the overcoat alone may not be sufficient. As previously noted, a thin lubricant layer is applied to the carbon overcoat and serves as an additional protective layer to the recording media. However, the thin lubricant layer must provide not only corrosion protection to the recording media, but should also provide good bonding and work well with the carbon overcoat. If the lubricants are not strongly bonded to the carbon overcoat layer, water and contaminants can displace them and render them ineffective for corrosion protection.

Magnetic recording discs typically include a substrate, such as an aluminum-magnesium (AlMg) or a silicon-oxide (SiO₂) alloy, and a magnetic recording medium, typically either a cobalt based metal alloy or a gamma iron oxide film. In order to prevent corrosion of the magnetic recording medium, a protective overcoat, such as a sputter-deposited carbon-containing overcoat, is formed over the magnetic recording medium layer. A lubricant layer, such as a fluoroether lubricant, is often applied to the carbon-containing overcoat for further protection to reduce the shear stresses between the read/write head and disc during contact. However, if the lubricant layer does not bond well with the carbon-containing layer, lubricant will tend to deplete due to spin-off during operation of the magnetic disc drive. If the lubricant layer is too thin, the read/write head can cause damage or wear to the disc surface. If the lubricant layer is too thick, the read/write head can become stuck to the surface when the disc drive is turned off, causing damage to the disc and/or the read/write head when the disc drive is turned back on. In addition to being viscous to reduce the shear stresses between the read/write head and disc, the lubricant should also exhibit corrosion resistance properties to aid in preventing media corrosion.

A necessary condition for media corrosion is the contact of the magnetic media with environmental oxidizing species, such as water and other contaminants. If these environmental oxidizing species can be denied access to the magnetic media, media corrosion can be effectively prohibited. In an effort to reduce media corrosion, it is proposed to utilize a lubricant/carbon overcoat having a very low surface energy. As a result of such low surface energy, the lubricant/carbon overcoat surface will not adsorb water and other contaminants, thus reducing the risk of media corrosion. While most of the conventional lubricants used for magnetic recording discs have a very low surface energy, less than 25 mJ/m², if these lubricants are not strongly bonded to the carbon surface, as is often the case, water and other contaminants can displace the lubricants thus rendering them ineffective for corrosion protection. Therefore, strong bonding between the lubricants and carbon layers is a key in enhancing the media corrosion performance of the lubricant/carbon protective overcoat.

The present invention is directed toward overcoming one or more of the above-mentioned problems.

### SUMMARY OF THE INVENTION

A protective overcoat layer having enhanced corrosion resistance properties is provided according to the present invention for use on magnetic recording discs. The protective overcoat layer includes a carbon layer, and a lubricant layer on top of the carbon layer, with the lubricant layer having a >CNO functional end group. The carbon layer may have a thickness less than 40 Å, while the lubricant layer may have a thickness is less than 20 Å.

In one form, the carbon layer is doped with either hydrogen (H-doped), nitrogen (N-doped) or fluorine (F-doped). The lubricant Z-disoc, commercially available from Montedison S.p.A. of Milan, Italy under the “FOMBLIN” tradename, is the one lubricant having a >CNO functional end group.

In another form, the lubricant layer includes a mixture of Z-disoc and other functional and/or non-functional perfluoropolyether lubricants. Examples of functional perfluoropolyether lubricants that may be included in the mixture are Z-diac, Z-dol, Z-dol-TX and Z-tetraol, while examples of non-functional perfluoropolyether lubricants that may be included in the mixture are Z-15 and Z-25, with all of the above-identified perfluoropolyether lubricants also commercially available from Montedison S.p.A. of Milan, Italy under that “FOMBLIN” tradename. The concentration of Z-disoc that may be present in the mixture can range from 1-100%. The chemical structures of each of the perfluoropolyether lubricants is provided below in Table 1.

TABLE 1

| Lubricant | Formula |
|---|---|
| Z-disoc | OCN—(C₆H₄)NHCO—CF₂—O—(CF₂—CF₂—O)ₘ—(CF₂—O)ₙ—CF₂—CO—NH—(C₆H₄)CH₂NCO |
| Z-diac | HOOCCF₂O(CF₂CF₂O)ₘ(CF₂O)ₙCF₂COOH |
| Z-dol | HO₂HC—CF₂—O—(CF₂—CF₂—O)ₘ—(CF₂—O)ₙ—CF₂—CH₂OH |
| Z-dol-TX | HOₚ(CH₂—CH₂O)—CH₂—CF₂—O—(CF₂—CF₂—O)ₘ—(CF₂—O)ₙ—CF₂—CH₂(O—CH₂—CH₂₎ₚOH |
| Z-tetraol | HO₂HC(HO)HC₂HCO₂HC—CF₂—O—(CF₂—CF₂—O)ₘ—(CF₂—O)ₙ—CF₂—CH₂OCH₂CH(OH)CH₂OH |
| Z-15 | CF₃—CF₂—O—(CF₂—CF₂—O)ₚ—(CF₂O)_{q}—CF₂—CF₃ |
| Z-25 | CF₃—CF₂—O—(CF₂—CF₂—O)ₚ—(CF₂O)_{q}—CF₂—CF₃ |

In yet another form, the lubricant layer includes first and second layers of lubricant. The first layer is deposited on top of the carbon layer and includes a lubricant having a >CNO functional end group, such as Z-disoc. The second layer is deposited on top of the first layer and includes the other functional and/or non-functional perfluoropolyether lubricants previously mentioned. The first layer of lubricant preferably has a thickness between 1-15 Å, with the second layer of lubricant having a thickness such that the total thickness of the first and second lubricant layers is less than 20 Å.

A method of protecting a magnetic recording disc including a disc substrate having magnetic recording media thereon is also provided according to the present invention. The inventive method includes the steps of depositing a carbon layer on the magnetic recording media, and depositing a lubricant layer on the carbon layer, the lubricant layer having a >CNO functional end group. The carbon layer may be deposited on the magnetic recording media using a variety of techniques, such as, but not limited to, DC magnetron sputtering, RF sputtering, PVD (Physical Vapor Deposition), CVD (Chemical Vapor Deposition), PECVD (Plasma-Enhanced Chemical Vapor Deposition), ion-based beam or cathodic arc processes. The lubricant layer maybe deposited on the carbon layer by a variety of techniques, such as, but not limited to, in-situ or ex-situ dip-lube or vapor lube processes.

It is an aspect of the present invention to reduce head-to-media separation in magnetic disc drives.

It is a further aspect of the present invention to reduce the signal-to-noise ratio in magnetic disc drives.

It is yet a further aspect of the present invention to improve the corrosion resistance properties of the protective overcoat layer used on magnetic recording discs.

It is an additional aspect of the present invention to reduce the overall thickness of the protective overcoat layer used on magnetic recording discs.

It is yet an additional aspect of the present invention to improve the bonding between the lubricant and carbon layers utilized as a protective overcoat for magnetic recording discs.

Other aspects and advantages of the present invention can be obtained from a study of the specification, the drawings, and the appended claims.

### BRIEF DESCRIPTION OF THE DRAWINGS

FIG. 1 is a side view of a schematic of a magnetic recording disc having a protective overcoat layer according to the present invention;

FIG. 2 is a graph of water contact angle versus lubricant type illustrating the water contact angle for various types of lubricants utilized in a protective overcoat layer;

FIG. 3 is a graph of lubricant thickness versus type of lubricant illustrating the maintained lubricant after degrease for various types of lubricants utilized in a protective overcoat layer;

FIG. 4 is a graph of corrosion charge versus type of lubricant illustrating the potentiostatic corrosion charge for both Z-disoc and Z-tetraol utilized as a lubricant in a protective overcoat layer; and

FIG. 5 is a side view of a schematic of a magnetic recording disc including a protective overcoat layer according to an additional embodiment of the present invention.

### DETAILED DESCRIPTION OF THE INVENTION

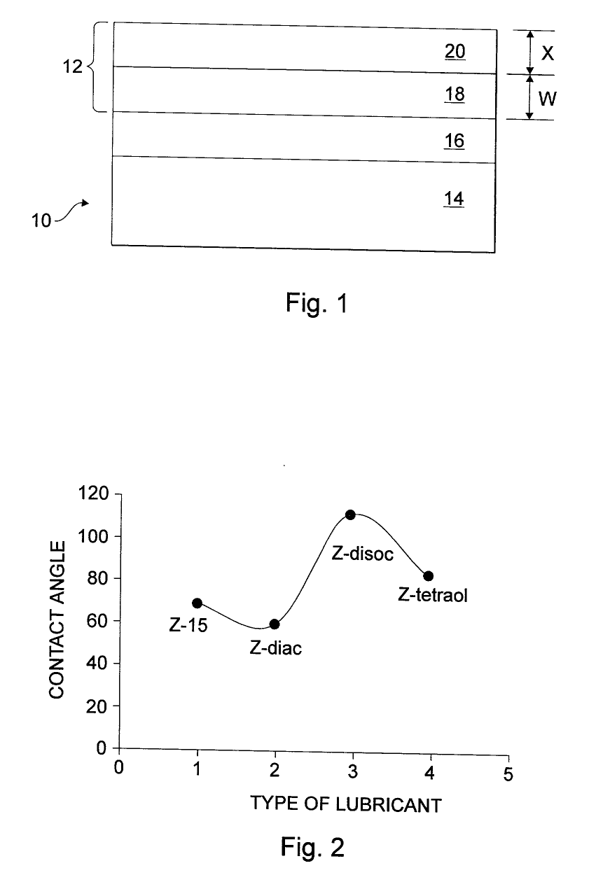

FIG. 1 illustrates a magnetic recording disc, shown generally at 10, incorporating a protective overcoat layer 12 in accordance with the present invention. The magnetic recording disc 10 includes a disc substrate 14, typically made of AlMg, glass, quartz, Si, SiO₂ or ceramic, and a magnetic recording medium layer 16, typically made of a cobalt based metal alloy or a gamma iron oxide film. However, both the disc substrate 14 and the magnetic recording medium layer 16 can be made of other materials without departing from the spirit and scope of the present invention.

The protective overcoat layer 12 includes a carbon-containing layer 18 deposited on top of the magnetic recording medium 16, and a lubricant layer 20 deposited on top of the carbon-containing layer 18. The carbon-containing layer 18 includes a thin amorphous carbon overcoat of doped or non-doped carbon. The carbon may be doped with hydrogen (H-doped), nitrogen (N-doped), fluorine (F-doped), and the like. Non-doped carbons may include, but are not limited to, carbons such as a filtered cathodic arc carbon. While the carbon-containing layer 18 may have a thickness W of up to 100 Å, one example of the thickness W of the carbon-containing layer 18 is less than 40 Å. The carbon-containing layer 18 may be deposited onto the magnetic recording medium 16 using a variety of techniques, including, but not limited to, DC magnetron sputtering, RF sputtering, PVD, CVD, PECVD, ion-beam or cathodic arc processes.

The lubricant layer 20 includes a low surface energy lubricant having a >CNO functional end group. Such a lubricant has been found to interact strongly with the carbon-containing layer 18. One such lubricant that has a >CNO functional end group is Z-disoc. The lubricant Z-disoc has a very high contact angle, which means that it also has a low surface energy. Due to the low surface energy, Z-disoc will not adsorb water and other contaminants which are a major cause of media corrosion. In addition to Z-disoc, any other lubricants having >CNO as a functional end group that interacts strongly with carbon may be utilized without departing from the spirit and scope of the present invention. While the lubricant layer 20 may have thickness X of up to 25 Å, one example of the thickness X of the lubricant layer 20 be less than 20 Å. The lubricant layer 20 may be applied by a variety of techniques, including, but not limited to, in-situ or ex-situ dip-lube or vapor lube processes.

The inventive protective overcoat 12 has been tested for corrosion performance and found to possess better corrosion properties than any of the carbon/lubricant overcoats currently in use. The protective overcoat layer 12 that was tested utilized the lubricant 20 having a functional end group as >CNO, and more specifically the lubricant Z-disoc. The Z-disoc lubricant layer 20 was applied, using a dip-lube process, onto the sputter deposited amorphous carbon overcoat layer 18 (H— and N-doped). The lubricant properties of Z-disoc were then compared with other lubricants, namely, Z-tetraol, Z-diac and Z-15, all of which were applied under the same deposition conditions to the same H— and N-doped carbon overcoat. All of the lubricants had a thickness of approximately 20 Å. As shown in FIG. 2, of all the lubricants tested, the Z-disoc lubricant had the highest water contact angle (WCA), and thus the best corrosion resistance properties. As shown in FIG. 2, the Z-disoc had a water contact angle of a little over 110°, compared with the water contact angles of the other lubricants of Z-tetraol (a little over 80°), Z-15 (approximately 70°) and Z-diac (approximately 60°). The higher the water contact angle of the lubricant the better it is at repelling water and other contaminants, and thus is more effective in preventing media corrosion. Of the lubricants tested, the Z-disoc lubricant clearly had the best corrosion resistant properties.

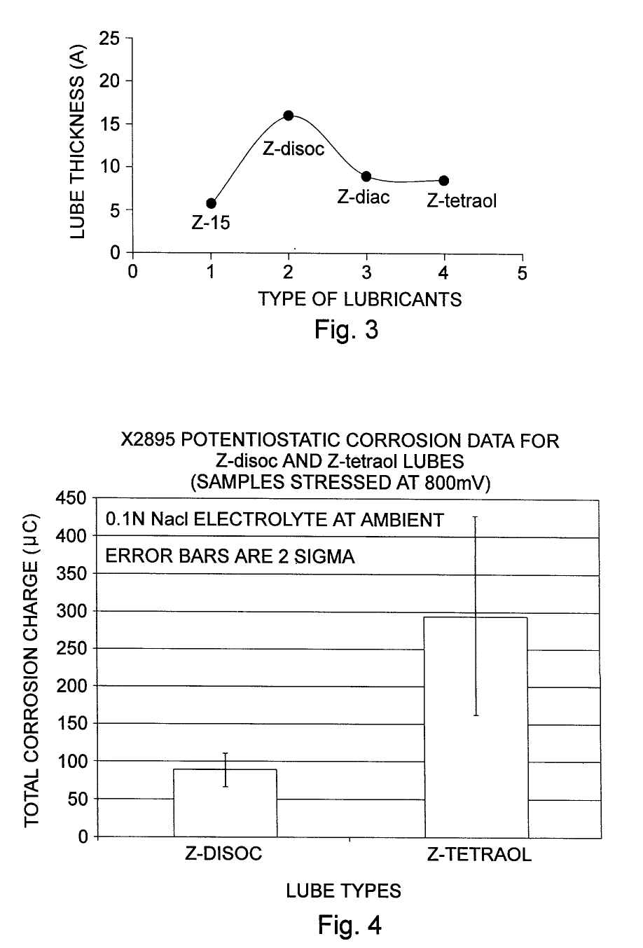

Using the same tested lubricants as described above, applied under the same deposition conditions to the same H— and N-doped carbon overcoat, the percentage of lubricant bonding to the carbon overcoat was evaluated and the results are illustrated in FIG. 3. The graph of FIG. 3 illustrates the thickness of the retained lubricant after a conventional degrease. As shown in FIG. 3, the lubricant thickness measurement indicates a higher bonded lube ratio to the carbon layer utilizing Z-disoc as compared to the other lubricants. The initial thickness of the lubricants was 20 Å, and as shown in FIG. 3 after a conventional degrease, the Z-disoc lubricant still maintained a thickness of approximately 16 Å, while only approximately 9 Å of both Z-diac and Z-tetraol remained, and only approximately 6 Å of Z15 remained. Thus, in addition to having the highest water contact angle of any of the lubricants tested, the Z-disoc lubricant also had the highest bonded lube ratio to the carbon layer. The higher the bonded lube ratio of the lubricant to the carbon layer, the stronger the bond formed between the lubricant and the carbon layer and the less likely the lubricant is to be displaced. Thus, a lubricant with a higher bonded lube ratio has the advantage that it will not wear out as quickly as a lubricant with a lower bonded lube ratio.

FIG. 4 illustrates the potentiostatic corrosion data at 800 mV for a magnetic recording media having an H— and N-doped carbon overcoat with lubricant layers of Z-disoc and Z-tetraol applied thereto under the same deposition conditions. In FIG. 4, the corrosion charge for the same recording media (same magnetic and carbon layers) that were Tubed with Z-disoc and Z-tetraol lubricants is plotted in the y-axis. Potentiostatic corrosion performance is measured as the amount of corrosion charge, i.e, current, produced by the recording media after being immersed in an electrolyte for a predetermined amount of time at a fixed polarization potential. The higher the corrosion charge given out by the recording media, the worse the corrosion resistance provided by the protective overcoat of carbon and lubricant. As shown in FIG. 4, the corrosion performance of an overcoat including a carbon layer (H— and N-doped) and a 20 Å lubricant layer of Z-disoc is at least three times better than a protective overcoat consisting of a carbon layer (H— and N-doped) and a 20 Å lubricant layer of Z-tetraol. Thus, as evidenced by the test results depicted in FIGS. 2-4, the lubricant Z-disoc, when used in conjunction with the carbon layer, clearly had the overall best corrosion resistance properties.

In cases where durability requirements desire a certain lubricant mobility, the lubricant layer 20 may include a mixture of a highly bonded lubricant having a >CNO functional end group, such as Z-disoc, and more mobile lubricants, such as, but not limited to, Z-diac, Z-dol, Z-dol-TX, and Z-tetraol (functional perfluoropolyether lubricants), and Z-15 and Z-25 (non-functional perfluoropolyether lubricants). Depending upon the particular durability requirements, the concentration of highly bonded lubricant (Z-disoc) in the mixture can vary from 1-100%.

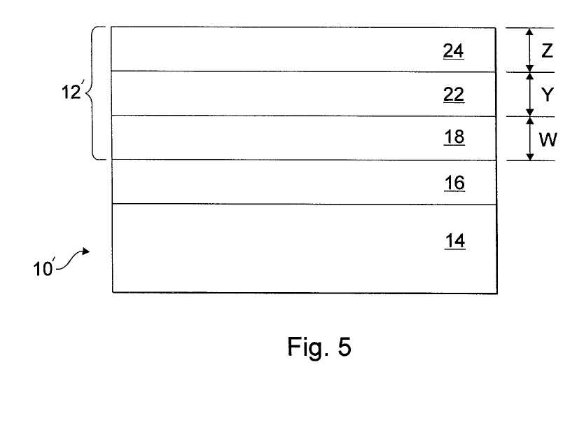

Instead of depositing the lubricant layer 20 in a mixture, dual lubricant layers may be provided as shown in FIG. 5, with like elements of FIG. 1 indicated with the same reference number and those elements requiring modification indicated with a prime (′). As shown in FIG. 5, the magnetic recording disc 10′ includes a protective overcoat 12′ having the carbon-containing layer 18 on the recording medium 16 and first 22 and second 24 layers of lubricant deposited on top of the carbon-containing layer 18. The first layer of lubricant 22 includes a highly bonded lubricant having a >CNO functional end group, such as Z-disoc. The first lubricant layer 22 is applied to the carbon-containing layer 18 and is strongly bonded thereto. The second lubricant layer 24 may include more mobile lubricants, such as, but not limited to, other functional (Z-diac, Z-dol, Z-dol-TX, Z-tetraol, etc.) and/or non-functional (Z-15, Z-25, etc.) perfluoropolyether lubricants. Each of the first 22 and second 24 lubricant layers may be deposited according to a variety of known techniques, including, but not limited to, in-situ or ex-situ dip-lube or vapor lube processes. In one example, the first layer 22 of strongly bonded lubricant has a thickness Y between 1-15 Å, with the thickness Z of the second layer 24 of more mobile lubricant being such that the total thickness (Y+Z) of the first 22 and second 24 lubricant layers is less than 20 Å.

While the present invention has been described with particular reference to the drawings, it should be understood that various modifications could be made without departing from the spirit and scope of the present invention. For example, while Z-disoc has been described as the preferred lubricant having a >CNO functional end group, any lubricant having a functional end group as >CNO may be utilized without departing from the spirit and scope of the present invention.

We claim:

1. A protective overcoat layer for a magnetic recording disc, said protective overcoat layer comprising:
a carbon-containing layer; and
a lubricant layer on top of the carbon-containing layer, the lubricant layer having a >CNO functional end group.

2. The protective overcoat layer of claim 1, wherein the carbon-containing layer comprises an H-doped, N-doped or F-doped carbon layer.

3. The protective overcoat layer of claim 1, wherein the lubricant layer comprises a layer of Z-disoc.

4. The protective overcoat layer of claim 1, wherein the carbon-containing layer has thickness less than 20 Å.

5. The protective overcoat layer of claim 1, wherein the lubricant layer comprises a mixture of Z-disoc and other functional and/or non-functional perfluoropolyether lubricants, wherein the Z-disoc is present in the mixture at a concentration of 1 to 100%.

6. The protective overcoat layer of claim 5, wherein the functional perfluoropolyether lubricants are selected from the group consisting of Z-diac, Z-dol, Z-dol-TX and Z-tetraol, and wherein the non-functional perfluoropolyether lubricants are selected from the group consisting of Z-15 and Z-25.

7. The protective overcoat layer of claim 1, wherein the lubricant layer comprises:
a first layer of lubricant having a >CNO functional end group on top of the carbon-containing layer; and
a second layer of other functional and/or non-functional perfluoropolyether lubricants on top of the first layer.

8. The protective overcoat layer of claim 7, wherein the first layer of lubricant comprises Z-disoc.

9. The protective overcoat layer of claim 7, wherein the first layer of lubricant has a thickness between 1-15 Å, and wherein the second layer of lubricant has a thickness such that a total thickness of the first and second lubricant layers is less than 20 Å.

10. The protective overcoat layer of claim 7, wherein the functional perfluoropolyether lubricants are selected from the group consisting of Z-diac, Z-dol, Z-dol-TX and Z-tetraol, and wherein the non-functional perfluoropolyether lubricants are selected from the group consisting of Z-15 and Z-25.

11. A method of protecting a magnetic recording disc including a disc substrate having magnetic recording media thereon, said method comprising:
depositing a carbon-containing layer on the magnetic recording media; and
depositing a lubricant layer on the carbon-containing layer, the lubricant layer having a >CNO functional end group.

12. The method of claim 11, wherein the carbon-containing layer has a thickness less than 40 Å, and wherein the lubricant layer has a thickness less than 20 Å.

13. The method of claim 11, wherein the carbon-containing layer is deposited on the magnetic recording media by DC magnetron sputtering, RF sputtering, PVD, CVD, PECVD, ion-beam or cathodic arc processes.

14. The method of claim 11, wherein the lubricant layer is deposited on the carbon-containing layer by in-situ or ex-situ dip-lube or vapor lube processes.

15. The method of claim 11, wherein the carbon-containing layer comprises H-doped, N-doped or F-doped carbon.

16. The method of claim 11, wherein the lubricant comprises Z-disoc.

17. The method of claim 11, wherein the lubricant layer comprises a mixture of Z-disoc and other functional and/or non-functional perfluoropolyether lubricants, wherein the Z-disoc is present in the mixture at a concentration of 1 to 100%.

18. The method of claim 17, wherein the functional perfluoropolyether lubricants are selected from the group consisting of Z-diac, Z-dol, Z-dol-TX and Z-tetraol, and wherein the non-functional perfluoropolyether lubricants are selected from the group consisting of Z-15 and Z-25.

19. The method of claim 11, wherein the step of depositing a lubricant layer on the carbon-containing layer comprises:
depositing a first layer of lubricant having a >CNO functional end group on top of the carbon-containing layer; and
depositing a second layer of other functional and/or non-functional perfluoropolyether lubricants on top of the first lubricant layer.

20. The method of claim 19, wherein the first layer of lubricant comprises Z-disoc, wherein the functional perfluoropolyether lubricants are selected from the group consisting of Z-diac, Z-dol, Z-dol-TX, and Z-tetraol, and wherein the non-functional perfluoropolyether lubricants are selected from the group consisting of Z-15 and Z-25.

21. The method of claim 19, wherein the first layer of lubricant has a thickness between 1-15 Å, and wherein the second layer of lubricant has a thickness such that a total thickness of the first and second lubricant layers is less than 20 Å.
